(19) United States
(12) Patent Application Publication
(10) Pub. No.: US 2010/0294560 A1
(43) Pub. Date: Nov. 25, 2010

(54) MOUNTING DEVICE FOR MOUNTING ELECTRIC COMPONENTS

(76) Inventor: Torben Dahl, Silkeborg (DK)

Correspondence Address: JAMES C. WRAY, 1493 CHAIN BRIDGE ROAD, SUITE 300, MCLEAN, VA, 22101, US

(21) Appl. No.: 12/735,203

(22) PCT Filed: Dec. 18, 2008
(86) PCT No.: PCT/DK2008/050323

§ 371 Date: Jul. 28, 2010

(30) Foreign Application Priority Data
Dec. 21, 2007 (PA) PA 2007 01858

(51) Int. Cl. H05K 5/00; H02G 3/08

(52) U.S. Cl. 174/520; 174/50

(57) ABSTRACT

A mounting device for mounting electric components in a plate-shaped element, as e.g. walls, ceilings or other similar elements of the type mounted from the side of the element from which the electric component is to be viewed, operated or accessible in other ways, the device including: an inner mounting box; an outer mounting box; a retaining means; where each mounting box consists of a bottom and a wall surrounding the bottom, and that the boxes are largely rotationally symmetric about an axis in parallel with the wall such that the boxes can be arranged coaxially and partly within each other, and that means are provided by which it is ensured that a predefined minimum distance is kept between the bottoms of the boxes.

### FIELD OF THE INVENTION

The present invention concerns a mounting device for mounting electric components in a plate-shaped element.

### BACKGROUND OF THE INVENTION

Similar devices are known e.g. from the applicant's previous designs published in WO 03/081054 or WO 2005/101602.

In addition a spotlight construction suitable to be built-in, in relatively thin furniture plate members is suggested in DE 29718829. In order to arrange the spot light in the plate, a groove or recess is provided in a hole in the plate member. One exterior member of the spot-light thereafter is able to be clicked into the hole and engage the recess, thereby maintaining the spotlight in position. In order to provide heat shield between the heat source and the plate member a number of concentric members made from various materials are provided, such that an overall shallow construction is achieved. Furthermore the light source and its protective glass clicks into place with the concentric members. The spotlight construction is only suitable for spotlights. The heat generation by the halogen light source is relatively high, and the highest temperature will be present adjacent the reflector shield immediately adjacent the electrical wiring. Hereby is created a potential fire hazard as well as general problem relating to expected service time of the construction.

However, new regulations and corresponding law have produced a need for this type of mounting devices to meet additional requirements, including to enable mounting electric components with great heat emission without influencing the structure behind, as well as the stability of such a device should be improved.

### OBJECT OF THE INVENTION

The present invention thus provides a mounting device which, besides allowing for it to be mounted from the front side of the plate-shaped element in which the electric component is to be accessible, provides for a fixed, stable mounting as well as the integrated insulation ensuring that the surrounding construction is not exposed to detrimental heat action, even when strongly heat transmitting electric components as e.g. halogen lamps in the mounting device are mounted therein.

### DESCRIPTION OF THE INVENTION

The invention provides such a mounting device having the characteristics that the device includes:
an inner mounting box;
an outer mounting box;
a retaining means;
   where each mounting box consists of a bottom and a wall surrounding the bottom, and that the boxes are largely rotationally symmetric about an axis in parallel with the wall such that the boxes can be arranged coaxially and partly within each other, and that means are provided by which it is ensured that a pre-defined minimum distance is kept between the bottoms of the boxes.

By ensuring in this way that a double bottom is provided in the mounting box, it is safeguarded that the heat possibly developed by the electric component to be mounted in the box itself will be insulated from the surrounding structure by means of the air space in the rearmost part of the box.

In a further preferred embodiment, the invention is characterised in that the inner mounting box has a diameter at the bottom which is less than the inner diameter of the outer mounting box at the bottom, and that one or more conical zones are provided in a part of or along the entire periphery of the wall away from the bottom, wherein the diameter of the box is greater than the bottom diameter.

By this design it is ensured that the inner box can be mounted coaxially within the outer box, and that the conical zones in a part of for along the entire periphery of the wall away from the bottom will be fixed with the free edge on the outer mounting box, such that the two mounting boxes are secured in relation to each other. By furthermore providing the conical zones at a suitable distance from the bottom of the inner mounting box, the air space between the two boxes may thus be secured and retained even under strong mechanical action by the mounting device.

In a further preferred embodiment of the invention, at the free end of the wall, i.e. the end of the wall not connected with the bottom, the outer mounting box is provided with a number of tabs with a certain length in direction of the wall. When the inner mounting box is inserted in the outer mounting box, the tabs will be deflected e.g. by contact with the conical zones as described with reference to the embodiment above such that there will be a certain spring action at the insertion of the inner box in the outer box.

Furthermore, it will be such that the conical zones, whether they interact with the tabs or without tabs, will entail that the box when inserted in a pre-drilled hole in a plate-shaped element may be fixed by the plate-shaped element and thereby retained mechanically in a safe way.

In a further preferred embodiment, the retaining means may either be fastened to the outer mounting box or be integrated in it, where the retaining means has a projecting retainer arm projecting largely perpendicularly to the axis of symmetry of the boxes.

This retaining means will therefore be located over the ceiling or behind the plate-shaped element, ensuring that the box is not inadvertently removed or loosened from the element in which it is mounted. Furthermore, the retaining means may be designed in such a way that it bears against the back side of the element, thus keeping the mounting device fixed in relation to the element in which the mounting device is mounted.

In a further preferred embodiment, the retainer arm is made of a resilient material, and a partially round-arched part is provided at the end of the arm opposite the outer mounting box.

The resilient design means that the mounting device to a certain extent will be kept fixed in the mounting hole provided in the plate-shaped element as well as the partially round-arched part outermost on the retainer arm will ensure that the mounting device can be displaced along the back side of the plate element during mounting, and if there should be obstacles here, the round-arched part may slide across these. It is particularly interesting where the mounting device is situated in ceilings, so-called list ceilings, where there will be grooves in the ceiling covering at the back side of the ceiling, and due to the round-arched part it will be possible to ensure that the mounting device itself may be displaced past these grooves without getting stuck. Moreover, cables, wires or other minor obstacles will often be located at the back side of a plate-shaped element, and the round-arched part will thus ensure that these will not obstruct in the correct mounting of the mounting device.

In a further preferred embodiment, the retaining means is provided with means for fastening/mounting an electric transformer. Particularly in the embodiments of the invention where there is provided a partly round, curving part outermost on the retainer arm, the retainer arm will have a certain distance down to the back side of the plate-shaped element in which the mounting device is mounted. When furthermore an electric transformer is mounted on the retaining means itself, the air under the retaining means between the retaining means and the back side of the plate-shaped element will ensure that an insulation is provided such that the heat developed by the transformer in connection with use of the electric component fitted in the mounting box will not damage, discolour or influence the plate-shaped element in other ways.

In a further preferred embodiment, the inner mounting box has means at the inner side of the wall for securing an electric component, e.g. a downlight, spotlight or the like. These means may e.g. be in the form of grooves or a screw thread such that an electric component may either be displaced into the mounting box and by means of projecting grooves on the electric component engage corresponding grooves at the inner side of the wall, or in the embodiments where the grooves are in the form a screw thread the electric component may be screwed in, and hence the correct distance between the front side of the electric component and the plate-shaped element in which the mounting device is fitted can be finely adjusted to the exact desired mounting position.

In a further preferred embodiment, mechanical assembling means are provided between the inner and the outer mounting box. In that way is provided that the two coaxially arranged mounting boxes cannot be displaced in relation to each other, even during long-time use, or where jolts and movements in the plate-shaped element may occur. The mechanical means may e.g. be in the shape of a screw or a bolt assembly.

In order to achieve optimal degree of insulation, the invention is designed in a further preferred embodiment in that the boxes and the retaining means are made of synthetic material, preferably plastic, including in particular plastic suited for injection moulding.

### DESCRIPTION OF THE DRAWING

The invention will now be explained with reference to the accompanying drawing, wherein

FIG. 1 shows an embodiment of the invention in exploded view;

FIG. 2 shows in the invention in a situation of use;

FIG. 3 illustrates a further embodiment including a transformer; and

FIG. 4 illustrates a cross-section through an embodiment of the invention illustrating the heat insulation.

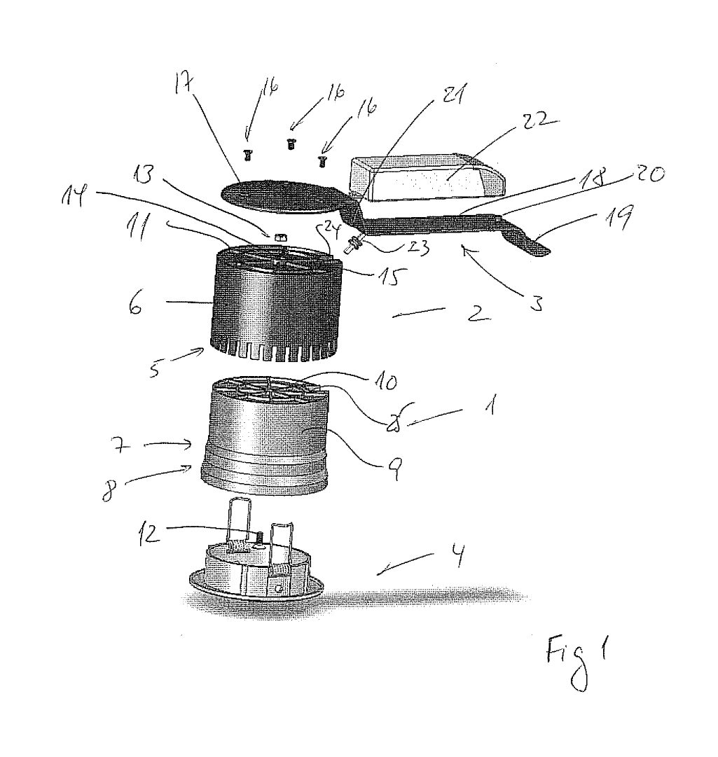

In FIG. 1 is shown a mounting device according to an embodiment of the invention. The mounting device is built up of an inner member or box 1, and outer member or box 2 and a retaining means 3. Additionally is illustrated an electric component 4 in the form of the frame for a halogen lamp. The inner and the outer boxes 1, 2 are displaced into each other such that the tabs 5 at the lower rim of the wall 6 of the outer box engage conical zones 7 or 8 provided on the outer wall 9 of the inner box 1. The tabs and the conical zones 7, 8 are of course dimensioned such that they by mechanical compression will form a cavity between the bottom 10 on the inner box and the bottom 11 on the outer box. The two boxes 1, 2 are secured partly by means of the tabs 5 interacting with the conical zones 7 or 8 and also, by the mechanical means in the form of a bolt 12 which is fastened to a nut 13. The nut is retained in a recess 14, which in this embodiment is moulded in the bottom 11 on the outer box 2.

Also, at the bottom 11 on the outer box 2 holes are provided in which is arranged screw threads. These holes 15 are designed such that they may receive the screws 16 which can be inserted in the holes 17 on the retaining means 3, such that the retaining means 3 may be screwed to the bottom 11 of the outer mounting box 2. Moreover, the retaining means 3 is provided with an arm 18 at the outer end of which there is provided a round, curving part 19. Moreover, on the retainer arm 18 there are provided means 20, 21 that enable mounting of an electric transformer 22 on the retainer arm.

In order that a wire (not shown) can be lead to the electric component illustrated by the frame 4, lead-ins 23, 24, 25 are provided in all components. Moreover, the wire lead-in 23 is provided with a packing such that it is ensured that there is an air- and gastight lead-in for the wire to the transformer for the electric component. This is important with regard to the building regulations that prescribe buildings to be made with a certain tightness. Hereby it is ensured that this particular design of the mounting device is ensured the greatest possible airtightness in spite of cutting a mounting hole in a plate-shaped element (not shown).

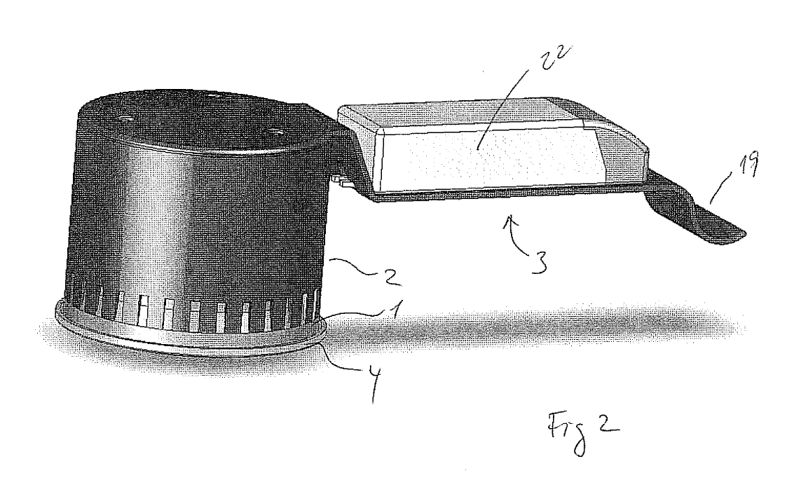

By mounting a mounting device as described above, a hole corresponding to the conical sections 7, 8 on an external wall 9 of the outer mounting box 1 is drilled. The box is assembled in beforehand, i.e. before mounting it will have an appearance as on FIG. 2, after which the retaining means 3 is passed through the hole in the plate-shaped element in which the mounting device is to be mounted. Since the hole has a diameter corresponding to the conical sections 7, 8, it will thus be possible to insert the entire mounting device from the front side through the mounting hole provided in the plate-shaped element.

In FIG. 2 is illustrated an assembled mounting device ready for being fitted in a plate-shaped element.

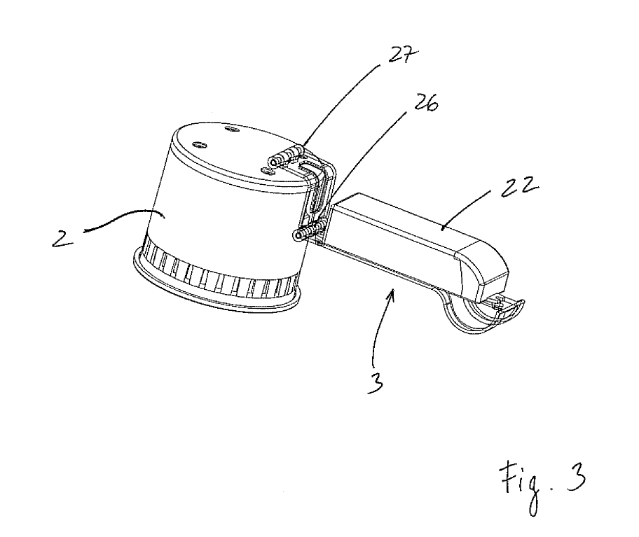

In FIG. 3 is illustrated a further embodiment/development of the insert described with reference to FIGS. 1 and 2.

By providing the retaining element 3 with two pivot points 26, 27, it is possible to manoeuvre the insert through a hole in a plate member (not illustrated) and place the insert including the retaining element with the transformer 22 in places where the overall height for example between the ceiling and another construction is relatively shallow. Only very little extra height, compared to the overall height of the insert is required. This is due to the fact that the retaining element may be straightened, bend etc according to the conditions were it is to be installed.

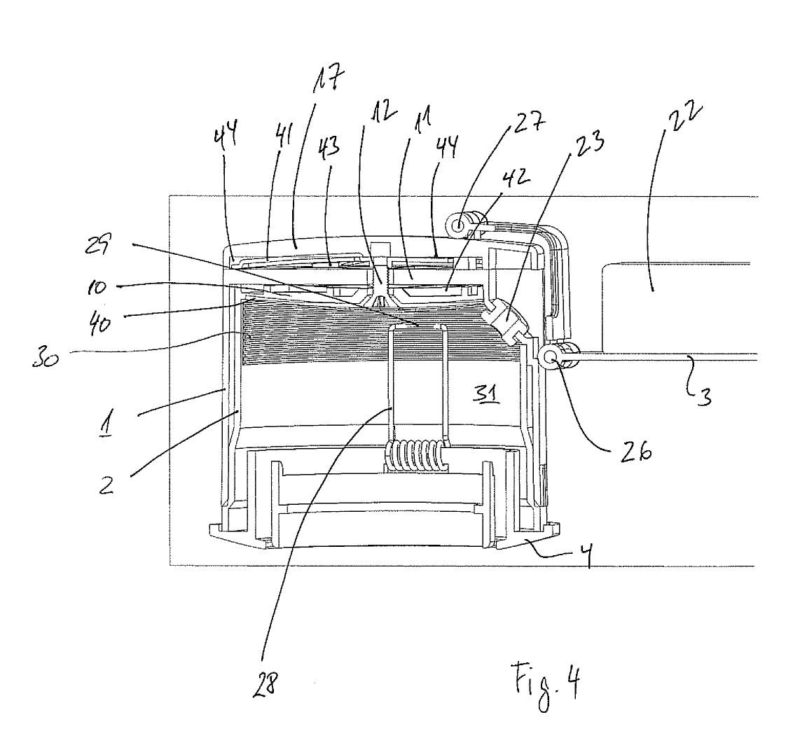

Turning to FIG. 4 a cross section through the insert according to FIG. 3 is illustrated. The cover plate 4 surrounding a light fixture is provided with resilient fixing means 28. The top of the resilient fixing means are provided with a point 29 which point 29 engages ridges 30 provided on the inner surface 31 of the inner member 2. The ridges may be in the shape of a thread, such that by turning the cover plate 4 perfect adjustment of the cover plate relative to the surrounding surface may be achieved.

An especially advantageous feature is provided in the top section of the insert. For a number of installations, especially in narrow or confined spaces heat is a problem. For this purpose a special heat shield is incorporated in the top section.

The heat shield consists of two stainless steel plates 40, 41, which are arranged on either side of the bottom of the inner member 2. The bolt 12 is used to connect and retain the inner member 2 relative to the outer member 1. In this embodiment the bolt 12 is further used in order to fix the plates 40, 41. In this manner three insulating pockets are created. A first pocket 42, between the plate 40 and the bottom of the inner member 2, a second pocket 43 between the second plate 41 and the bottom of the inner member 2, and a third pocket 44, between the second plate 41 and the outer member 1. The insulation provided has reduced the heat flux from the insert such that for example with a 20 W halogen light source the surface temperature is 60° C. and for a 35 W light source the temperature is 73-75° C. Both measurements according to the F-HAT testing and certification regime. In this connection it shall be noticed that the temperature in the immediate vicinity of these types of light sources is between 120° C. and 135° C.

This aspect is important. Although according to EN 60 598-1:2000 and EN 60 598-2-1:1989 the allowable temperature is 90° C., a number of materials used in the construction industry, will be damaged at 70° C. and above—for example polymer foils used as moisture membranes.

1. A mounting device for mounting electric components in a plate-shaped element, as e.g. walls, ceilings or other similar elements of the type mounted from the side of the element from which the electric component is to be viewed, operated or accessible in other ways, wherein the device includes:
an inner mounting box (1);
an outer mounting box (2);
a retaining means (3);
where each mounting box consists of a bottom (10, 11) and a wall (6, 9) surrounding the bottom, and that the boxes (1, 2) are largely rotationally symmetric about an axis in parallel with the wall such that the boxes can be arranged coaxially and partly within each other, and that means are provided by which it is ensured that a pre-defined minimum distance is kept between the bottoms of the boxes, and that the inner mounting box (1) has means (30) at the inner side of the wall (31) for securing an electric component, e.g. a downlight, spotlight, switch or the like.

2. Mounting device according to claim 1, wherein the inner mounting box has a diameter at the bottom which is less than the inner diameter of the outer mounting box at the bottom, and that one or more conical zones are provided in a part of or along the entire periphery of the wall away from the bottom, wherein the diameter of the box is greater than the bottom diameter.

3. Mounting device according to claim 1 wherein at the free end of the wall, i.e. the end of the wall not connected with the bottom, the outer mounting box is provided with a number of tabs with a certain length in direction of the wall.

4. Mounting device according to claim 1, wherein the retaining means may either be fastened to the outer mounting box or be integrated in it, and that the retaining means has a projecting retainer arm projecting largely perpendicularly to the axis of symmetry of the boxes.

5. Mounting device according to claim 4, wherein the retainer arm is made of a resilient material, and that a partially round-arched part is provided at the end of the arm opposite the outer mounting box.

6. Mounting device according to claim 1 wherein the retaining means is provided with means for fastening/mounting an electric transformer.

7. Mounting device according to claim 1, wherein the inner mounting box has means at the inner side of the wall for securing an electric component, e.g. a downlight, spotlight or the like.

8. Mounting device according to claim 1, wherein mechanical assembling means are provided between the inner and the outer mounting box.

9. Mounting insert according to claim 1 wherein on opposite sides of the bottom 10 of the inner insert 2 and the bottom 11 of the outer insert 11 are arranged steel plates, preferably stainless steel plates, substantially having an area equal to the respective bottoms inner areas, an where the steel plates arches away from the respective bottoms.

10. Mounting insert according to claim 1 wherein the mounting member 3 is provided with two or more pivot points 26, 27, such that the mounting member 3 may be folded on itself.
